(19) United States
(12) Patent Application Publication
(10) Pub. No.: US 2015/0228813 A1
(43) Pub. Date: Aug. 13, 2015

(54) CONTINUOUS RESONANT TRAP REFRACTORS, LATERAL WAVEGUIDES AND DEVICES USING SAME

(71) Applicant: SOLARSORT TECHNOLOGIES, INC., Barrington, RI (US)

(72) Inventors: Shalom Wertsberger, Rochester, NY (US); Jeffrey C Andle, Falmouth, ME (US)

(21) Appl. No.: 14/426,738

(22) PCT Filed: Sep. 9, 2013
(86) PCT No.: PCT/US2013/059101

§ 371 Date: Mar. 7, 2015

Related U.S. Application Data
(63) Continuation-in-part of application No. 13/831,575, filed on Mar. 14, 2013.
Application No. 13/831,575 is a continuation-in-part of application No. 13/685,691, filed on Nov. 26, 2012, now Pat. No. 8,530,825.
Application No. 13/685,691 is a continuation-in-part of application No. 13/726,044, filed on Dec. 22, 2012, now Pat. No. 8,532,448.
(60) Provisional application No. 61/786,357, filed on Mar. 15, 2013.
(60) Provisional application No. 61/801,431, filed on Mar. 15, 2013.
(60) Provisional application No. 61/801,619, filed on Mar. 15, 2013.
(60) Provisional application No. 61/701,687, filed on Sep. 16, 2012.
(60) Provisional application No. 61/713,602, filed on Oct. 14, 2012.
(60) Provisional application No. 61/718,181, filed on Oct. 24, 2012.
(60) Provisional application No. 61/723,832, filed on Nov. 8, 2012.
(60) Provisional application No. 61/724,920, filed on Nov. 10, 2012.

(30) Foreign Application Priority Data
Dec. 14, 2012 (GB) 1222557.9

(51) Int. Cl. H01L 31/0232; H01L 31/12; H01L 27/142

(52) U.S. Cl. CPC H01L 31/02327; H01L 27/142; H01L 31/125

(57) ABSTRACT

A CRTR (Continuous Resonant Trap Refractor) is the name given to waveguides having a tapered core and a cladding which disperses radiant energy admitted via the aperture at the wide end of the tapered core, and emits the energy in sorted fashion via the cladding. As individual waves reach a width of the core in which they can not propagate along the tapered core waveguide, and are emitted via the cladding sorted at frequency dependent depth. Alternatively, the CRTR admits radiant energy via the cladding and mixes and emits the combined energy via the aperture. The present invention is directed The invention discloses several uses of CRTRs and aspects of the invention include inter alia imagers, camouflage devices, radar and heat signature reduction devices, communications, target designation, and the like.

### RELATED APPLICATIONS

Aspects of the present invention were first disclosed in U.S. Patent Application 61/701,687 to Andle and Wertsberger, entitled “Continuous Resonant Trap Refractor, Waveguide Based Energy Detectors, Energy Conversion Cells, and Display Panels Using Same”, filed 16 Sep. 2012. Further refinements of the tapered waveguide based Continuous Resonant Trap Refractor (CRTR) and to lateral waveguides with which CRTRs may cooperate, were disclosed together with various practical applications thereof in the following additional U.S. Patent Applications: 61/713,602, entitled “Image Array Sensor”, filed 14 Oct. 2012; 61/718,181, entitled “Nano-Scale Continuous Resonance Trap Refractor”, filed 24 Oct. 2012; 61/723,832, entitled “Pixel Structure Using Tapered Light Waveguides, Displays, Display Panels, and Devices Using Same”, filed 8 Nov. 2012; 61/723,773, entitled “Optical Structure for Banknote Authentication”, filed 7 Nov. 2012; Ser. No. 13/726,044 entitled “Pixel Structure Using Tapered Light Waveguides, Displays, Display Panels, and Devices Using Same”, filed 22 Dec. 2012; Ser. No. 13/685,691 entitled “Pixel structure and Image Array Sensors Using Same”, filed 26 Nov. 2012; Ser. No. 13/831,575 entitled “Waveguide Based Energy Converters, and energy conversion cells using same” filed Mar. 15, 2013; 61/786,357 titled “Methods of Manufacturing of Continuous Resonant Trap Structures, Supporting Structures Thereof, and Devices Using Same” filed Mar. 15, 2013, 61/801,619 titled “Tapered Waveguide for Separating and Combining Spectral Components of Electromagnetic Waves” filed Mar. 15, 2013, U.S. 61/801,431 titled “Continues Resonant Trap Refractors, lateral waveguides, and devices using same” filed Mar. 15, 2013, all to Andle and Wertsberger; and 61/724,920, entitled “Optical Structure for Banknote Authentication, and Optical Key Arrangement for Activation Signal Responsive to Special Light Characteristics”, filed 10 Nov. 2012, to Wertsberger. Furthermore Patent application GB 1222557.9 filed Dec. 14, 2012 claims priority from U.S. 61/701,687. All of the above-identified patent applications are hereby incorporated herein by reference in their entireties.

### FIELD OF THE INVENTION

The present invention relates generally to optical nanostructures and devices using the same, and more particularly to spatially separating and/or combining radiant energy and devices using same in conjunction with electrical to radiant energy inter-transducers.

### BACKGROUND

Various areas of physics require spatially separating radiant energy into its spectral components such as frequency and/or polarization. By way of example such fields include solar cells, image array sensors, filters, energy harvesting devices, certain types of reflectors, and the like. Similarly, various areas will benefit from mixing various spectral components into a broader type of radiant energy, combining a plurality of ‘narrower’ spectral components into a ‘broader’ radiant energy.

In its most basic form, the term ‘refraction’ means the change of direction of a ray of light, sound, heat, radio waves, and other forms of wave energy, as it passes from one medium to another. Generally waves of different frequencies would refract at different angles and thus refraction tends to spatially separate multispectral radiation into its component frequencies.

Radiant energy extends over a very broad radiation spectrum, and the spectrum to which different aspects of the invention may be applicable ranges from the Ultra Violet (UV), via the visible light portion of the spectrum, to Infra Red (IR) and beyond into the millimeter wave range, also known as Extremely High Frequency (EHF). In some applications this spectrum may extend even to the microwave range. Many applications would need to cover only portions of this spectrum. It is seen therefore that the application at hand determines the spectral range of interest, and that a spectral range of interest may differ by application, an apparatus, or a portion thereof. Regarding lateral waveguides, yet another aspect described below, each waveguide may have its own spectrum of interest, which may differ from the spectral range of interest of an adjacent waveguide. Therefore, the spectral range of interest is defined herein as relating to any portion or portions of the total available spectrum of frequencies which is being utilized by the application, apparatus, and/or portion thereof, at hand, and which is desired to be detected and/or emitted utilizing the technologies, apparatuses, and/or methods of the invention(s) described herein, or their equivalents.

Structure to facilitate conversion of radiant energy to electricity or electrical signals (hereinafter “LE”), or conversion of electrical signals into radiant energy such as light (hereinafter “EL”) are known. Collectively, objects, materials, and structures, which perform conversion between two forms of energy, or adjust and control flow of energy, are known by various names which denote equivalent structures, such as converters, transducers, absorbers, detectors, sensors, and the like. To increase clarity, such structures will be referred to hereinunder as ‘transducers’. By way of non-limiting examples, the term “transducer” relates to light sources, light emitters, light modulators, light reflectors, laser sources, light sensors, photovoltaic materials including organic and inorganic transducers, quantum dots, CCD and CMOS structures, LEDs, OLEDs, LCDs, receiving and/or transmitting antennas and/or rectennas, phototransistors photodiodes, diodes, electroluminescent devices, fluorescent devices, gas discharge devices, electrochemical transducers, and the like.

A transducer of special construction is the RL transducer, which is a reflective transducer. Reflective transducers controllably reflect radiant energy. Such transducers may comprise micro-mirrors, light gates, LCD, and the like, positioned to selectively block the passage of radiant energy, and reflect it into a predetermined path, which is often but not always, the general direction the energy arrived from. Certain arrangements of semiconductor and magnetic arrangements may act as RL transducers by virtue of imparting changes in propagation direction of the radiant energy, and thus magnetic forces or electrical fields may bend a radiant frequency beam to the point that in effect, it may be considered as reflected. RL transducers may be fixed, or may be used to modulate the energy direction over time. Passive transducers such as LCD and micromirrors fall into the reflective device when used to reflect incoming energy, but when used in conjunction with at least one light source may be considered LE type transducers.

The skilled in the art would recognize that certain LE transducers may act as EL transducers, and vice versa, with proper material selection, so a single transducer may operate both as EL and LE transducer, depending on the manner of operation. Even certain RL transducers may act as another transducer type. Alternatively transducers may be built to operate only as LE, as RL, or as EL transducers. Furthermore, different types of transducers may be employed in any desired combination, so the term transducers may imply any combinations of LE, EL, and RL, as required by the application at hand.

Presently the most common structures for LE conversion are photovoltaic (PV) which generally use layers of different materials. In a PN based transducer, a PN junction is formed at the interface of a positive and negative doped semiconductor materials to form photoactive semiconductor based PN junction devices. When exposed to a photon having energy equaling or higher than the band gap between the junction materials, the photon energy causes formation of electron-hole groups, which are separated and collected on both sides of the junction depletion zone. Those transducers are colloquially known as inorganic transducers. Organic transducers utilize somewhat different mechanisms, generally with hetherojunctions of polymers and/or small molecules, however the skilled in the art would recognize the similarity between those transducer types and relate to them equivalently as applied to certain aspects of the present invention. Notably, certain PN junction type are commonly used as LE transducers, such as LED, OLED, semiconductor lasers, and the like. Charge Coupled Devices (CCD), and Complementary Metal Oxide Semiconductor (CMOS) are two common type of image sensing technology.

Other types of transducers utilize antennas, and more commonly rectennas, to achieve the energy conversion. The term rectenna relates to an antenna structure having a rectifier integrated with, or closely coupled to, the antenna, such that electromagnetic energy incident on the antenna is rectified and presented as primarily unidirectional (ideally DC) signal. By way of example, rectennas are described in U.S. Pat. No. 7,799,998 to Cutler, and in “Nanoscale Devices for Rectification of High Frequency Radiation from the Infrared through the Visible: A New Approach”, N. M. Miskovsky, P. H. Cutler, A. Mayer, B. L. Weiss, Brian Willis, T. E. Sullivan, and P. B. Lerner, Journal of Nanotechnology, Volume 2012, Article ID 512379, doi:10.1155/2012/512379, Hindawi Publishing Corporation©. which is incorporated herein by reference in its entirety.

Waveguides are a known structure for trapping and guiding electromagnetic energy along a predetermined path. An efficient waveguide may be formed by locating a layer of dielectric or semiconducting material between cladding layers on opposite sides thereof, or surrounding it. The cladding may comprise dielectric material or conductors, commonly metal. Waveguides have a cutoff frequency, which is dictated by the wave propagation velocity in the waveguide materials, and the waveguide width. As the frequency of the energy propagating in the waveguide approaches the cutoff frequency Fc, the energy propagation speed along the waveguide is slowed down. The energy propagation of a wave along a waveguide may be considered as having an angle relative to cladding. This angle is determined by the relationship between the wavelength of the wave and the waveguide width in the dimension in which the wave is being guided. If the width of the waveguide equals one half of the wave wavelength, the wave reaches resonance, and the energy propagation along the waveguide propagation axis stops. The condition where energy is at or close to such resonance will be termed as a stationary resonant condition.

Tapered waveguide directed at trapping radiant energy, as opposed to emitting energy via the cladding, have been disclosed by Min Seok Jang and Harry Atwater in “Plasmionic Rainbow Trapping Structures for Light localization and Spectrum Splitting” (Physical Review Letters, RPL 107, 207401 (2011), 11 Nov. 2011, American Physical Society©). The article “Visible-band dispersion by a tapered air-core Bragg waveguide”, (B. Drobot, A. Melnyk, M. Zhang, T. W. Allen, and R. G. DeCorby, 8 Oct. 2012/Vol. 20, No. 21/OPTICS EXPRESS 23906, ©2012 Optical Society of America “Visible-band dispersion by a tapered air-core Bragg waveguide” B. Drobot, A. Melnyk, M. Zhang, T. W. Allen, and R. G. DeCorby, 8 Oct. 2012/Vol. 20, No. 21/OPTICS EXPRESS 23906, ©2012 Optical Society of America) describes out-coupling of visible band light from a tapered hollow waveguide with TiO2/SiO2 Bragg mirrors. The mirrors exhibit an omnidirectional band for TE-polarized modes in the ˜490 to 570 nm wavelength range, resulting in near-vertical radiation at mode cutoff positions. Since cutoff is wavelength-dependent, white light is spatially dispersed by the taper. These tapers can potentially form the basis for compact micro-spectrometers in lab-on-a-chip and optofluidic micro-systems. Notably, Bragg mirrors are very frequency selective, complex to manufacture, and require at least a width higher than ¾ wavelength to provide any breadth of spectrum. In addition to the very narrow band, the Bragg mirrors dictate a narrow bandwidth with specific polarization, while providing however a fine spectral resolution.

A Continuous Resonant Trap Refractor (CRTR) is the name used in these specifications to denote a novel structure which is utilized in many aspects of the present invention. As such, a simple explanation of the principles behind its operation is appropriate at this early stage in these specifications, while further features are disclosed below.

A CRTR is a structure based on a waveguide having a tapered core, the core having a wide base face forming an aperture, and a narrower tip. The core is surrounded at least partially by a cladding which is transmissive of radiant energy under certain conditions. The CRTR may be operated in splitter mode, in a mixer/combiner mode, or in a hybrid mode providing combination of mixer and splitter mode. In splitter mode the radiant energy wave is admitted into the CRTR via the aperture, and travels along the depth direction extending between the aperture and the tip. The depth increases from the aperture towards the tip, such that larger depth implies greater distance from the aperture. The core is dimensioned such that at least some of the admitted frequencies will reach a state where they will penetrate the cladding, and be emitted therefrom. This state is referred to as Cladding Penetration State (CPS), and is reached when energy of a certain frequency approaches a critical width of the waveguide for that frequency. The mechanism at which cladding penetration state occurs may vary, such as by tunneling penetration, skin depth penetration, a critical angle of incidence with the cladding and the like. Generally CPS will occur in proximity to, or at the width, where the wave reaches a resonance, known as the critical frequency for that width, and conversely as the critical width for the frequency, of the wave. Regardless of the mechanism, a CPS is characterized by the wave reaching a frequency dependent depth within the CRTR where it is emitted via the cladding. The decreasing width of the core will dictate that a lower frequency wave will reach CPS before higher frequency waves, and will penetrate the cladding and exit the waveguide at a shallower depth than at least one higher frequency wave. As waves of differing frequencies will be emitted via the cladding at differing depths, the CRTR will provide spatially separated spectrum along its cladding. Notably, in certain CRTR embodiments some frequency components of the incoming energy may be emitted via the tip, in non-sorted fashion.

Conversely, when operated in mixer/combiner mode, a wave coupled to the core via the cladding, at, or slightly above, a depth where it would have reached CPS in splitter mode, will travel from the emission depth towards the aperture, and different waves coupled to the core through the cladding will be mixed and emitted through the aperture. Coupling energy into the CRTR core from the cladding, will be referred to as ‘injecting’ or ‘inserting’ energy into the CRTR. It is noted that in most if not all practical cladding materials the energy will refract when entering and exiting the cladding. Therefore, the energy source will be located at a different depth than the point of desired entry into the core. The depth at which the wave would couple into the tapered core is somewhat imprecise, as at the exact depth of CPS the wave may not couple best into the core, thus the term ‘slightly above’ as referred to the coupling of energy into the tapered core in combiner/mixer mode should be construed as the depth at which energy injected into tapered core via the cladding would best couple thereto to be emitted via the aperture, within certain tolerances stemming from manufacture considerations, precision, engineering choices and the like.

The term spectral component will relate to energy or a portion thereof, within the spectral range of interest, which is characterized by its frequency, polarization, phase, flux, intensity, incidence, radiosity, energy density, radiance, or a combination thereof.

A round cross section of the tapered core will be polarization neutral under most circumstances. Certain non-symmetrical or multi-faceted symmetrical tapered core forms will however cause separation of the aperture-admitted radiant energy to be polarization sensitive. Thus, by way of example, a square pyramid or frustum CRTR core will separate incoming radiant energy into its component polarizations as well as by its frequency. Thus if two transducers are disposed in a first and a second path of energy emitted via the cladding, the first path exits the core at a first face, and second path exists the core at a second face disposed at an angle to the first face, the first transducer will receive a spectral component which differs from the spectral component received by the second face, at least by different polarization. This behavior will be reversed when the CRTR operates in mixer/combiner mode, such that energy emitted from the aperture will reflect the polarity created by separate sources, and injected into the CRTR at different faces. By way of none-limiting example, if light source A injects modulated energy into one face of the pyramidal core, and light source B injects differently modulated energy into a perpendicular face of core, the energy emitted by the aperture will have one spectral component at a first polarization reflecting the modulation of source A, and a second spectral component at 90° to the first spectral component, representing the modulation of source B. Therefore, Placing a plurality of EL transducers at different angular locations about the depth dimension of the CRTR, would result in combined polarized energy corresponding to the location of the transducers, being emitted via the aperture, when the transducers are energized.

CRTRs may also operate in reflective mode, by providing light gates which will reflect radiant energy back into the CRTR tapered core. A light gate disposed at the depth where radiant energy is emitted out of the cladding, will cause the emitted energy to be reflected back into the cladding, and thence emitted via the aperture. An array of CRTRs in conjunction with RL transducers which act as light-gates will have variable reflectivity such that at least a portion of the energy incident on the array at the associated frequency will be reflected, in accordance with the setting of the light gate reflectors. The term light gate should be construed to extend to the complete spectral range of interest, which is dictated by the application at hand. Therefore, a light gate may reflect energy well beyond the visible light. The broad band capabilities of the CRTR allows modulation of its reflectance over a broad band of frequencies, extending the ability for reflectance into the UV, IR, and even the mm wave spectrum. Reflective mode may also operate in polarization sensitive mode as explained above for EL and LE transducers in polarization sensitive mode.

A CRTR is considered to operate in hybrid mode when energy is both admitted and emitted via the aperture. In certain embodiment this mode involves energy being admitted via the aperture and at least portions thereof being emitted via the cladding, while other energy is being injected via the cladding and emitted via the aperture. In other embodiments a portion of the energy admitted via the aperture is selectively reflected back therethrough. A reflective CRTR is a CRTR cooperating with at least one RL transducer, and is also considered to operate at hybrid mode.

Thus functionally, a CRTR is a device which allows passage of radiant energy therethrough, while
a. imparting a change in the direction of propagation of incoming energy;
b. in one mode a CRTR is operational to spatially disperses incoming energy into spatially separated spectral components thereof, which are outputted via the CRTR cladding, the mode is equivalently referred to as disperser, splitter, or dispersion mode;
c. in another mode a CRTR is operational to combine a plurality of incoming spectral components into emitted energy comprising the components and emitted via the aperture, the mode equivalently referred to as combiner, mixer, or mixing mode; and,
d. in another mode the CRTR is operational to controllably reflect at least a portion of the spectral components admitted via the aperture, the reflected components being reflected via the aperture, thus controllable changing the effective reflectance of the CRTR at selected spectral components, the mode equivalently referred to as reflective mode or reflectance mode.
   As presented elsewhere in these specifications, a CRTR may be operated in a combination of these modes, and such mode is considered a hybrid mode.

The CRTR aperture is thus dimensioned, when operating in splitter mode, to allow the entry of a spectral component having at least the lowest frequency in the spectral range of interest, which means that the longest wavelength in the spectral range of interest for the CRTR is defined by the aperture width in at least one dimension. Notably, the spectral range of interest may be limited by other considerations to shorter wavelengths. The core taper in at least one dimension which must encompass both the emission width of the longest wave in the spectral range of interest as well as an emission width of at least one shorter wavelength within the spectral range of interest. The CRTR either will taper to less than the emission width of the shortest wave in the spectral range of interest or will allow the final portion of the spectral range of interest to exit vertically at a truncated tip of the core. Larger widths than those emission widths at the inlet aperture, or smaller widths than those emission widths at the tip, are allowed.

If the tip is truncated or otherwise allows passage of at least some of the spectral components that were admitted by the aperture, the highest frequency in the spectral range of interest for the CRTR is defined by the longest wavelength that will be emitted via the cladding. If the tip does not allow energy to pass therethrough, the highest frequency in the spectral range of interest for the CRTR is the highest frequency to be emitted via the cladding, and detected or reflected by any desired manner.

The spectral range of interest for a CRTR operated in mixer mode is the range between the highest and lowest frequencies of radiant energy injected into the tapered core via the cladding. In hybrid and reflective modes of operation the spectral range of interest for the CRTR is a combination of the above ranges, as dictated by the application at hand. Notably, all of those spectral ranges of interest are defined for the CRTR. Portions of the CRTR or other elements of the invention may have different ranges of interest.

A simplified view of a CRTR is provided in FIG. 1. A CRTR comprises a waveguide having a tapered core 73 and a cladding 710; the core having an aperture and a tip. The larger face (denoted Hmax) of the tapered waveguide core will be generally referred to as the CRTR aperture, and the smaller face, which may taper to a point, will generally be referred to as the tip. The axis X-X extending between the aperture and the tip would be referred to as the CRTR depth axis. The core is tapered, following any desired taper function and may be tapered by different amounts for any direction at any depth. However for clarity of basic description, the figure depicts a linear taper forming angle 760 between the cladding and the vertical. Radiant energy 730 admitted via the aperture travels generally along the depth axis; however, the energy may travel towards the aperture in mixer mode, away therefrom in splitter mode, or in both direction in any hybrid mode. In splitter mode a CRTR admits energy within a spectral range of interest via the aperture and emits it in a frequency sorted fashion via the cladding. A CRTR operating in mixer mode admits radiant energy via the cladding and mixes and emits the energy via the aperture. Notably, a certain angle shift occurs in the process, and thus, energy entering the CRTR from its aperture will be angled away, i.e. refracted, and emitted at an angle to the depth dimension in a splitter mode. In mixer mode energy entering the CRTR via the cladding will couple to the core and would be angled away from the direction in which it was injected, to propagate generally along the depth axis and emitted via the aperture. The CRTR has a width dimension in at least one direction substantially perpendicular to the depth axis. The core width varies in magnitude so as to be greater at the first end than at the second end. The core width is also dimensioned such that when multi-frequency energy is admitted through the core and propagates along the core depth, it will cause a lower frequency spectral component to reach a cladding penetration state at a first depth, and the core will further taper to a width that will cause energy of a higher frequency spectral component reach a cladding penetration state at a second depth, which is larger than the first depth. In most embodiments, this is achieved by having the width dimension taper to a size smaller than half wavelength of the shortest wave in the spectral range of interest of the CRTR, but in certain embodiments a portion of the spectral range of interest is emitted via the tip.

At its wider base known as the aperture, the CRTR has a width Hmax, which limits the lowest cutoff frequency Fmin. At the tip the tapered core width Hmin dictate a higher cutoff frequency Fmax. Between the aperture wide inlet and the narrower tip, the cutoff frequency is continually increased due to the reduced width. Energy, such as polychromatic light 730 is incident the aperture at an angle which permits energy admission. Waves having a lower frequency than the cutoff frequency Fmin are reflected 735. Waves 740 having frequency higher than Fmax exit through the CRTR core, if an exit exists. Waves having frequencies between Fmin and Fmax will reach their emission width, and thus their cladding penetration state, at some distance from the inlet of the waveguide depending on their frequency. The distance between the inlet and the emission width of a given frequency is the emission depth.

Thus, examining the behavior of a wave of arbitrary frequency Ft, where Fmin<Ft<Fmax, which enters into the CRTR core at its aperture at an incidence angle within an acceptance cone centered about the propagation axis X-X, the angle θ between the wave and X-X will vary as the wave propagates along the X-X axis due to the narrowing of the CRTR waveguide and increase of the cutoff frequency, as depicted schematically by Ft′. As the wave approaches depth X(Ft) where either the tapered waveguide cutoff frequency equals or nearly equals Ft, or the angle θ approaches the critical angle θ C, at which the wave can not propagate any further within the CRTR core. The wave Ft is thus either radiated through the dielectric cladding of the CRTR as shown symbolically by 750 and 752, or is trapped in resonance at depth X(Ft) in a metal clad CRTR. At that point the wave of frequency Ft reached its cladding penetration state at the emission depth dictated by the emission width of the tapered CRTR core. For a continuum of entering waves of different frequencies Fmin<F1, F2, . . . Fx<Fmax, entering the base of the tapered waveguide 71, it becomes a Continuous Resonant Trap Refractor (CRTR) in which the different frequency waves become standing waves, trapped at resonance in accordance to their frequency along the X-X axis. Such trapped waves are either leaked through the cladding by the finite probability of tunneling though the cladding or are lost to absorption in the waveguide. Note that since a CRTR will in general also cause admitted rays (speaking from the perspective of a CRTR operating in splitter mode) to be refracted or otherwise redirected so that the component(s) produced by splitting exit the CRTR at an angle to the CRTR depth axis, this will make it possible to employ a CRTR that has been embedded within stacked waveguides in such a manner that the CRTR directs specific components, e.g., spectral components, of the incoming multispectral radiation to predetermined waveguides.

Therefore, for a given CRTR spectral range of interest Si, ranging between λmax to λmin which represent respectively the longest and shortest wavelengths of the spectral range of interest as measured in the core material, wherein λ′ is at least one wavelength in Si, the dimensions of a frequency splitting CRTR taper are bounded such that
a. the aperture size ψ must exceed the size of one half of λmax;
b. the CRTR core size must also be reduced at least in one dimension, to at least a size ζ which is smaller than or equal to one half of wavelength λ′.

Thus the CRTR dimensions must meet at least the boundary of {ζ≦λ′/2<λmax/2≦ψ} where the CRTR sizes defined above relate to a size in at least one dimension in a plane normal to the depth dimension. In FIG. 4 the aperture size ψ=hmax. It is noted however that not all waves in Si must meet the condition b. above. By way of example, certain waves having shorter wavelengths than hmin/2 may fall outside the operating range of the CRTR. Such waves which enter the CRTR will either be emitted through the tip, reflected back through the aperture, or absorbed by some lose mechanism.

Notably if a third spectral component λ″ is present, and has a higher frequency than λ′, it may be emitted at greater depth than λ′ or be emitted or reflected via the tip, if the tip is constructed to pass a spectral component of frequency λ″.

It is noted that CRTR use may extend to the millimeter wave range (EHF), or even to the microwave range. Between cm waves and micron IR radiant energy the range of available dielectric constants increases dramatically. By way of example, water has an index of refraction of nearly 10 at radio frequencies but only 1.5 at IR to UV. There are numerous optical materials with low and high index at mm wave frequencies and below. Thus while the principles of operation of CRTRs are similar, the materials and sizes differ. A millimeter/microwave operated CRTR is a channelized filter integrated into a horn antenna wherein the channelized ports are lateral to the horn and the in-line exit port is a high pass filtered output for a broad band input. Such device may be utilized as a an excellent front end for a multiplexer/diplexer, and as a general purpose antenna that has excellent noise figure and improved anti-jamming as those characteristics are determined at the front en of devices which use them.

CRTRs are often disposed within a stratum. In some embodiments stratums comprise a plurality of superposed waveguides equivalently referred to as superposed waveguides, stacked waveguides, or lateral waveguides. In other embodiments the stratum comprises a slab of material that is transmissive of the radiant energy spectral range of interest. The CRTRs are disposed such that the CRTR depth direction is substantially perpendicular to the local plane of the stratum. Radiant energy emitted from the cladding is coupled to transducers within the stratum or via the stratum, and radiant energy from EL transducers within the stratum is coupled to the CRTR via the cladding.

In many embodiments that utilize lateral waveguide based stratum, transducers are embedded within the lateral waveguide. In certain embodiments the transducers are optimized for the frequency which is in the spectral range to which the corresponding waveguide is exposed. Conversely in certain embodiments the dimensions of the lateral waveguide is optimized for a transducer which emits energy of a certain frequency, however those are not requirements to many of the aspects of the present invention.

When combined with transducers, CRTRs are capable of providing a hyperspectral or multi-spectral pixels, which may be arranged in arrays. Those pixels act as a reversible channelized filter of light and other radiant energy, capable of operating from the long IR—and even to the millimeter wave radar and microwave regimes of the electromagnetic spectrum—to the deep UV. CRTRs are further capable of energy harvesting, as the channelized outputs are converted to electrical energy using photovoltaic and related processes.

CRTR based sensing pixels (generally referred to hereinafter as sensing pixels) utilize the CRTR or a portion thereof in splitter mode, to admit a broad bandwidth of energy via the aperture, and selectively channel portions of the admitted spectrum into frequency and/or polarization dependent locations, where the incoming energy may be converted into electrical energy by a plurality of LE transducers, the ordered outputs of which correspond to an image portion sensed by the pixel. Thus the sensing pixel is a combination of a CRTR and at least one EL transducer. Optionally a sensing pixel may also harvest some or all of the incoming energy for powering related circuitry, and/or emit energy.

CRTR based emitting pixels (generally referred to herein as emitting pixels) utilize the CRTR or portion thereof in mixer/combiner mode, to receive energy of varying spectral components via the cladding. The CRTR or a portion thereof is operated in mixer/combiner mode, wherein an array of weighted radiant energy sources serve as channelized inputs. Spectral components from the energy sources are fed into the CRTR core via the cladding, and are combined to emit the combined energy via the aperture, the spectral details of which are determined by the weighting of the spectral components of the energy sources. Different spectral components injected into the cladding will mix. Thus, by way of example, energy of frequency Fr, injected through the cladding into the tapered waveguide core, will mix with the energy of Fp. Therefore, assuming that the core material is equally transparent to components of the CRTR spectral range of interest, and that the optical loses in the core are negligible, the radiant energy emitted from the CRTR aperture would be the summation of the radiant energy injected into the core. The skilled in the art would readily recognize that by placing primary color light sources about the cladding any color light may be emitted through the aperture.

A common application of emitting pixels is a display within the visual range, but the spectral content of the radiation emitted by the pixel may range beyond the visual range, ranging from mm wave to UV. Static images may be provided through constant weighting of energy sources in the primary colors range, while photographic, video, and patterns may be provided by actively varying the weights of energy sources in an array of pixels. Thus the emitting pixel is a combination of a CRTR and at least one EL transducer. Optionally an emitting pixel may also harvest some incoming energy for powering related circuitry, and/or sense energy in certain bands.

Pixels may also have variable weighted reflectors located on one or more channelized ports such that at least a portion of the energy incident on the CRTR based pixel aperture, at the associated channel frequencies is programmably reflected. The reflectors form the RL type transducers disclosed above.

The path which a spectral component takes between the CRTR and its respective transducer constitute the channel. Channels may take many forms, such as lateral waveguides, paths within a slab stratum, other waveguides, and the like. A channel may also constitute a path between the CRTR core and a RL transducer even if such path is of minute length. In certain application the channel may be to an absorber which absorb the energy for storage, dispensing, as heat, and the like.

There are multiple fields of applications and requirement for devices to improve, enhance, and/or augment vision, including visualization of portions of the spectrum which lie outside the visual range. Various methods are employed to satisfy these requirements, and most involve a combination of energy sensing portion, and a display portion. In some embodiments, a transparent medium is utilized to view a scene, and a display portion is utilized to project or otherwise embed visual information into the transparent media, to augment the data seen by the user. The energy sensing portion may be broadly divided into passive imaging and active imaging methods (relying on ambient light or light emitted by the object to be viewed) and active (relying on a source of light generated by the apparatus) imaging.

Frequency translation of one frequency of radiant energy to another are commonly utilized, such as translation of Infra Red (IR) light into the visible spectrum. Image amplification is also commonly used, by sensing energy at certain portions of the spectrum and amplifying the sensed information by analog or digital means such as photon multiplication, on chip gain multiplication, and the like. Regardless of the technology through which an image is detected and redisplayed, there exists an ongoing demand for ever-improving signal to noise ratio, size weight and power (SWAP) reductions, pixel size reductions, and resolution improvements. There is a further need to efficiently combine detection methods in a single apparatus, such that an apparatus might augment low-light images with thermal imaging data and/or active IR illumination. Further needs of vision related devices may include dynamic change of energy transmission in all or a portion of the spectrum, in response to certain environments and the changes therewithin.

In some cases, thermal sources might not be imaged with adequate resolution or certainty due to neighboring materials that are reflective to the IR frequencies being imaged. Such IR reflectors are often polarization dependent reflectors due to the Brewster angle associated with one polarization and the efficient reflection of the other. Active and thermal sources will typically emit randomly polarized light while reflected images will exhibit some polarization preferences. Thus, a method of polarization selective detection is also desirable.

Regardless of the technology through which an image is detected and redisplayed, there exists an ongoing demand for ever-improving signal to noise ratio, size weight and power (SWAP) reductions, pixel size reductions, and resolution improvements. There is a further need to efficiently combine detection methods in a single apparatus, such that an apparatus might augment low-light images with thermal imaging data and/or active IR illumination by way of example. In certain applications, incorporating energy harvesting methods is also desired.

There is a critical and unmet need to reduce hide objects from infrared imaging, and radar, especially to hide the heat signature of fighters and military machinery.

### SUMMARY

Different aspects of the present invention utilize different capabilities of CRTR and arrays thereof, which may be operated as a multispectral capable photonic pixel which is capable of acting as a reversible channelized filter/combiner, capable of operating from the far IR and mm wave radar regime of the electromagnetic spectrum, to the deep Ultra Violet (UV) range. As such it is an object of the invention to provide CRTR based devices and systems that will improve existing radiant energy absorbing and emitting structures, and provide new uses therefore.

In a basic embodiment of the invention, there is provided a spectral refractor for splitting multi-frequency radiant energy into at least two spectral component thereof, the refractor comprising a tapered waveguide core having a first end and a second end, the first end defining an aperture, the core having a depth direction extending between the first end and the second end, wherein the depth magnitude increases with distance from the first end toward the second end. The core has a width dimension in at least one direction transverse to the depth direction, and the core width monotonically decreasing in magnitude as a function of the depth. A cladding is disposed at least partially around the core. The first end of the core is dimensioned to allow passage of radiant energy comprising of at least a first and a second spectral components, each having a frequency and/or a polarization associated therewith, wherein the first spectral component has a lower frequency than the second spectral component, and wherein the varying width of the core will cause the first and the second spectral components to reach a state at which they will penetrate the cladding at a respective first and second depths, wherein the first depth is less than the second depth.

optionally, the first and second spectral component are of different polarization, and the geometry of the core asymmetrical or multi-faceted symmetrical, and wherein the varying width combined with the core geometry will cause the two spectral component to reach a state at which they will penetrate the cladding and be emitted from the core at different directions. Optionally, the two spectral components will have both varying polarization and varying frequencies, in which case they will be emitted at a differing direction and depth, in a symmetrical multi-faceted core.

a CRTR based detecting pixel further comprises at least a first transducer and optionally a second transducers for converting radiant energy to electric energy, the first transducer disposed in a path to receive the first spectral component and the second transducer, if present, disposed in a path to receive the second component.

In still another basic embodiment of the invention, there is provided a spectral mixer to obtain radiant energy having at least two spectral components, the mixer comprising a tapered waveguide core having a first end and a second end, the first end defining an aperture, the core having a depth direction extending and monotonically growing from the first end towards the second end, the core having a width dimension in at least one direction transverse to the depth direction, and the core width monotonically decreasing in magnitude as a function of the depth. A cladding is disposed at least partially around the core. at least two radiant energy sources are disposed outside the cladding, each of the sources emitting a spectral component having at least one wavelength associated therewith. Each of the two energy sources are disposed in a path such that energy emitted therefrom will penetrate the cladding and couple to the core, at a depth where the core width is about an integer multiple of half of the respective wavelength. Preferably the integer multiple is one, and the core width is slightly larger than half the wavelength.

In order to simplify the description of different aspects of the invention embodying devices using CRTRs, FIG. 2 provides schematic symbols for the modes of operation of the different modes in which the CRTRs operate at least a portion of the time. FIG. 2(a) represent a generic symbol for a CRTR operating at any mode, and also shows schematically how lateral waveguides 210 are disposed relative to the CRTR core and cladding. FIG. 2(b) symbolically represents a CRTR operating as a refractor, also known as a disperser, or splitter, mode. FIG. 2(c) represents a CRTR operating in combiner mode, also known as a mixer mode, and FIG. 2(d) represents to a CRTR in mixed or hybrid mode, where the CRTR receives energy through the aperture and spatially separates it to spectral components and which receives energy via the cladding and combines and emits it via the aperture. Alternatively, the hybrid mode may be based on reflecting portions of the energy admitted via the aperture. Hybrid operation can be achieved by judicious selection of transducers disposed about the CRTR.

Notably, CRTR's may be deployed in combinations with lenses, collimators, and the like.

In some embodiments, the CRTR is embedded in a stack of lateral waveguides, each containing transducers, or acting as energy guides to transducers. The transducers may be optimized to the type of radiant energy received.

The design of the aperture diameter (typically between λ′max/2 and ˜λ′max, but optionally larger) and CRTR array spacing may be selected to optimize optical collection efficiency, pixel size, and/or angle of acceptance. The larger the diameter, the narrower the main diffraction lobe of the CRTR's acceptance pattern is; however, the larger the effective pixel spacing. The CRTR tapers to approximately half the wavelength of the shortest wave in the spectral range of interest, λ′min/2. Energy at shorter wavelengths is either absorbed, reflected, or passed through the CRTR. The dimensions are in wavelengths adjusted for the refractive index of the core material (λ′=λcore). The core material is highly transparent over the entire band.

CRTRs operating in splitter mode operate to detect energy such as by way of example a focal plane for a camera. CRTRs in splitter mode may also operate to harvest energy and convert it to electrical energy. When operated in mixer/combiner mode, CRTR based pixels may also be utilized for emitting light such as for a display devices, energy emitting sources such as light sources, antennas, or for creating arrays of steering emitted beams by phase interference between the various CRTRs in an array. Notably, the CRTR may be operated in a combination of different modes, thus, by way of example, a CRTR may have one LE transducer disposed to receive a certain spectral component and transform it to an electrical signal corresponding to the spectral component, while a second LE transducer may be disposed about the same CRTR but at another location and be operational to harvest the energy of another spectral component. The harvested energy may be used for any desired purpose, including powering other aspects of the device. An EL transducer may further be disposed, such that energy emitted therefrom will be coupled to the core via the cladding, and emitted via the aperture. A RL transducer coupled at yet another depth or orientation may cause admitted energy to be reflected via the aperture. Thus, a single CRTR based pixel may by way of example act as a pixel for sensing incoming blue light, harvest the energy of IR light, and use the energy to emit red light, all while reflecting green light. Pixel operating in more than one mode, will be considered as operating in both modes, and thus the pixel described above should be considered as an emitting pixel, a sensing pixel, and a reflecting pixel, all at the same time. Alternatively, in an array, different pixels may operate in different modes, or in hybrid mode.

Therefore in a basic embodiment of the invention there is provided a CRTR based pixel, which comprises a tapered waveguide core having a first end and a second end, the first end defining an aperture, the core having a depth direction extending between the first end and the second end, wherein the depth magnitude increases with distance from the first end toward the second end; the core having a monotonically decreasing width dimension in at least one direction transverse to the depth direction. A cladding is disposed at least partially around the core. To form a pixel, at least one transducer is coupled to the CRTR by being disposed about the cladding. The transducer may be disposed about the cladding by being positioned at least in part within the cladding, but more commonly being positioned near the cladding, or having a predetermined path by which energy emitted from the cladding will impinge on the transducer. Oftentimes the transducer will be disposed in a lateral waveguide in which the CRTR is embedded. The transducer may be a LE type, EL type, or RL type. When the transducer is a LE type transducer, it converts spectral components of radiant energy admitted into the aperture into electrical energy, in which case the pixel is a sensing pixel. When the transducer is an EL transducer which converts electrical energy into radiant energy to be injected into the tapered core and at least partially emitted via the aperture, the pixel forms an emitting pixel. When the transducer is a RL transducer, which receive a spectral component admitted via the aperture and controllably reflect the spectral component back into the tapered core for being emitted via the aperture the pixel is a reflecting pixel. Notably the pixel may have plurality of pixels from one or more types. When a pixel has at least two converters each being of different type, or when one transducer may be operated as more than one type, the pixel is considered to be a hybrid pixel. A hybrid pixel encompasses therein the two types of pixels dictated by the type of transducer or transducers. To ease coupling between the CRTR and the lateral waveguide in the various splitter modes, the core may be of higher refractive index than the cladding of the CRTR.

in an aspect of the invention, there is provided an imager comprising a plurality of CRTR based sensing pixels forming a sensor portion, the sensor being coupled to a display comprising of a plurality of CRTR based emitting pixels. In some embodiments at least some of the sensing pixels are configured to detect a plurality of polarizations. In some embodiments at least some of the emitting pixels are configured to emit energy in multiple polarizations. In certain embodiments at least one spectral frequency detected by the sensor or a portion thereof is emitted by the display or a portion thereof as a different spectral component, or stated differently the sensed spectral component is translated into another spectral component. Optionally the sensing pixels are arranged on one side of a substrate and the emitting pixels are arranged on an opposite side.

In more detail, the imager comprises a plurality of pixel elements, a pixel element being at least one sensing pixel and one emitting pixel, the sensing pixel comprising a plurality of transducers;
wherein the sensing pixel is configured to operationally separate radiant energy admitted via its aperture into a plurality of spectral components and direct the spectral components to corresponding transducers, for converting the spectral components into respective electrical signals;
the plurality of electrical signals is being manipulated and coupled to at least one transducer in the emitting pixel for converting the manipulated signals to energy;
wherein the emitting pixels are configured to receive energy from the at least one transducer therein, and emit visible light corresponding to the plurality of spectral components or a portion thereof; and,

Sensing pixels forming a sensor portion, at least one sensing and one emitting pixels. Each pixel comprises a CRTR and a plurality of transducers disposed outside the cladding, wherein in the sensing pixel is configured to operationally separate radiant energy admitted via its aperture into a plurality of spectral components and direct the spectral components to corresponding transducers, for converting the spectral components into respective electrical signals. The plurality of electrical signals is being manipulated and coupled to at least one transducer in the emitting pixel for converting the enhanced signals to energy. The emitting pixels are configured to receive energy from the at least one transducer therein, and emit visible energy corresponding to the plurality of spectral components or a portion thereof. The plurality of sensing pixels form a sensor portion of the imager, and the plurality of emitting pixels form a display portion of the imager. Optionally, at least one transducer is disposed within a lateral waveguide.

Spectral components may be separated by frequency, polarization or a combination thereof. In some cases the manipulation includes connecting a plurality of sensing transducers in serial and/or in parallel, to provide the desired amplification or power required for the corresponding pixel in the display. Spectral components sensed by a sensing pixel may be enhanced, attenuated, frequency translated, polarization translated, and the like. The spectral components may be manipulated temporally and/or spatially, allowing image enhancement. Manipulation may be dynamically modified responsive to incoming radiant energy, one or more external sensors, user preferences, and the like. Manipulation may further include amplification, attenuation, combination of outputs from a plurality of sensing pixel, combination of outputs from a plurality of transducer in the sensing pixel, digital signal processing, analog signal processing, and any combination thereof. In some embodiments the imager comprises, or is coupled to, an orientation sensor, and manipulation of the spectral components is dynamically modified in accordance with information provided by the orientation sensor. The imager may further comprise a lens or a collimator.

In another aspect of the invention there is provided A camouflaging device comprising a covering coupled to an object to be camouflaged. The coupling may be direct such having the camouflaging device be embedded in a coating of the device such as an outer layer of the device, or a coating applied directly to the device skin, or it may be a separate covering such as a camouflage net, clothing, camouflage panels, and the like. The coating comprises a plurality of emitting or reflecting pixels, and a controller coupled to the plurality of pixels for controlling the color of light respectively emitted or reflected therefrom. In certain embodiments at least one of the emitting pixels is operated in hybrid mode, and having at least one LE transducer for harvesting energy incident on the camouflage device. In certain embodiments at least one of the plurality of pixels is operated in hybrid mode having at least two transducers of differing types, the types selected from LE, EL or RL transducer, or the plurality of pixel comprises a combination of emitting pixels and reflecting pixels.

Optionally the camouflaging device further comprises an optical sensing device coupled to the controller, and in some embodiments the sensing device comprises a plurality of sensing pixels.

Several aspects of the invention, such as the camouflaging device, may benefit from an arrangement of a plurality of pixels for improved three dimensional pattern display and/or sensing, the arrangement comprising a plurality of pixels arrange within a protrusion or a depression, wherein the pixel apertures are oriented towards different directions at substantially normal angle to the faces of the protrusion or depression.

in an aspect of the invention there is provided a method for reducing heat signature of a vehicle having a body forming at least a partial envelope, and having at least one heat producing component at least partially disposed within the envelope. The method comprises the step of disposing a radiant energy to electrical energy converter (LE type) between at least a portion of the heat producing component and the envelope, the converter having an active face directed toward the heat producing component, and thus the active face will absorb heat emitted from the component and convert it to electrical energy, reducing energy leaving the vehicle, thus reducing its heat signature. While any converter of heat to electricity would reduce the heat signature, optionally, the converter may comprise at least one planar LE transducer disposed within a lateral waveguide, and a plurality of tapered cores waveguides (CRTRs) disposed within the lateral waveguide, wherein the tapered cores having a wide end, and wherein the wide end of the plurality of CRTRs is directed toward the heat producing component, and the tapered cores are dimensioned to admit radiant energy from the heat producing component and direct at least a portion of the admitted energy to the LE transducer.

These and other aspects of the invention will be described in more details below.

### BRIEF DESCRIPTION OF THE DRAWINGS

The summary, above, and the following detailed description will be better understood in view of the enclosed drawings which depict details of preferred embodiments. It should however be noted that the invention is not limited to the precise arrangement shown in the drawings and that the drawings are provided merely as examples.

FIG. 1 depicts a simplified view of a CRTR.

FIG. 2 depicts four schematic symbols for CRTRs operating in different modes.

FIG. 3A depicts a simplified embodiment of a single imager cell providing utilizing CRTRs, and providing radiant energy manipulation. while FIG. 3B provides similar ability, with simplified arrangement for frequency translation.

FIG. 3C depicts schematic diagram of a low power imager.

FIG. 4 depicts a portion of an array of pixels which form a camouflaging coating and/or device, for emitting a camouflage pattern by emitting pixels to assist in reducing the visual signature of an object.

FIG. 5 depicts an embodiment utilizing a plurality of CRTRs for reducing radar signature of objects such as vehicles, aircrafts, marine vessels, and the like.

FIG. 6 depicts top view of deployment of one embodiment of the camouflage arrangement.

FIG. 7A is a front view, and FIG. 7B is a side view, of a protrusion/depression which provides advantages for several embodiments.

FIG. 8 depicts a simplified arrangement using CRTR to absorb heat emitted from a heat source.

FIG. 9 depicts a simple arrangement of pixels acting as a phased array antenna.

FIG. 10 is a more detailed view of a portion of a larger phase array antenna.

FIG. 11 is more detailed depiction of the embodiment of FIG. 6.

FIG. 12 depicts one example of a multi-faceted symmetrical tapered core for a CRTR.

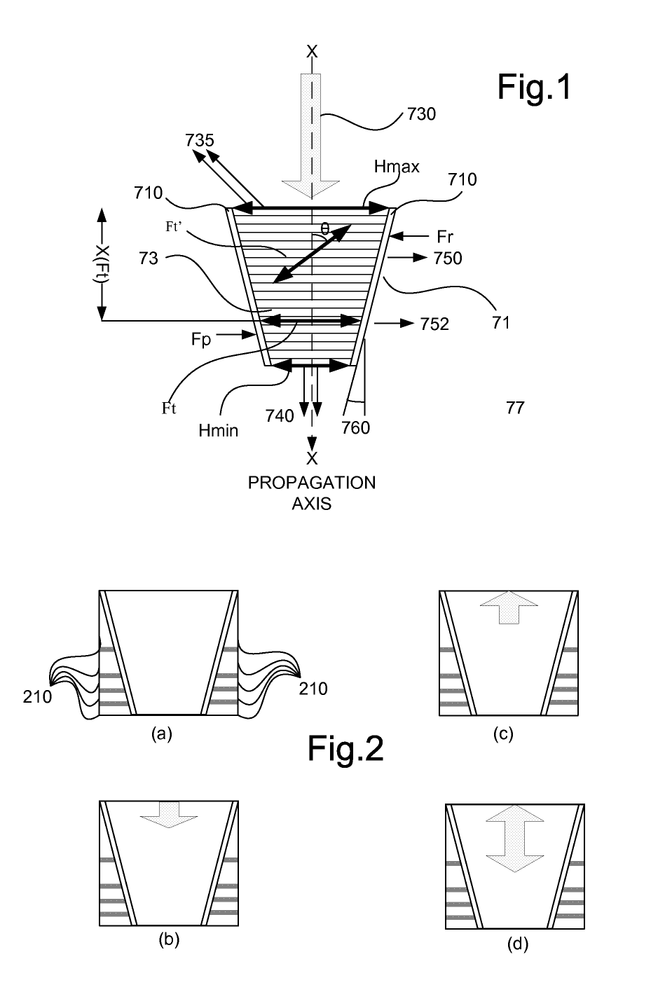

### DETAILED DESCRIPTION

Certain figures and embodiments of the invention will now be described by way of non-limiting example to increase the understanding of different aspects of the invention.

As described above, there are multiple fields of applications and requirement for devices to improve, enhance, or augment vision. CRTR based devices present excellent set of solutions for many of those requirements and needs. The principles behind such solutions will be described herein, and combinations of those principles may be adapted as needed for specific needs. The skilled in the art will easily modify the embodiments described herein to fit specific needs, in view of the principles disclosed herein.

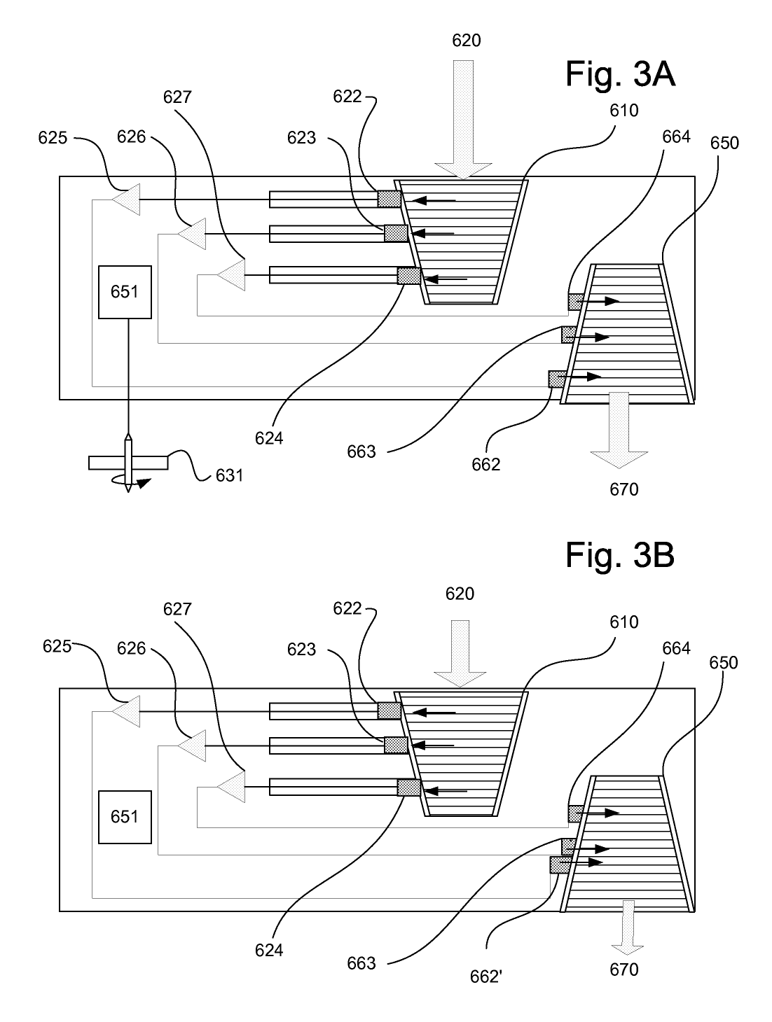

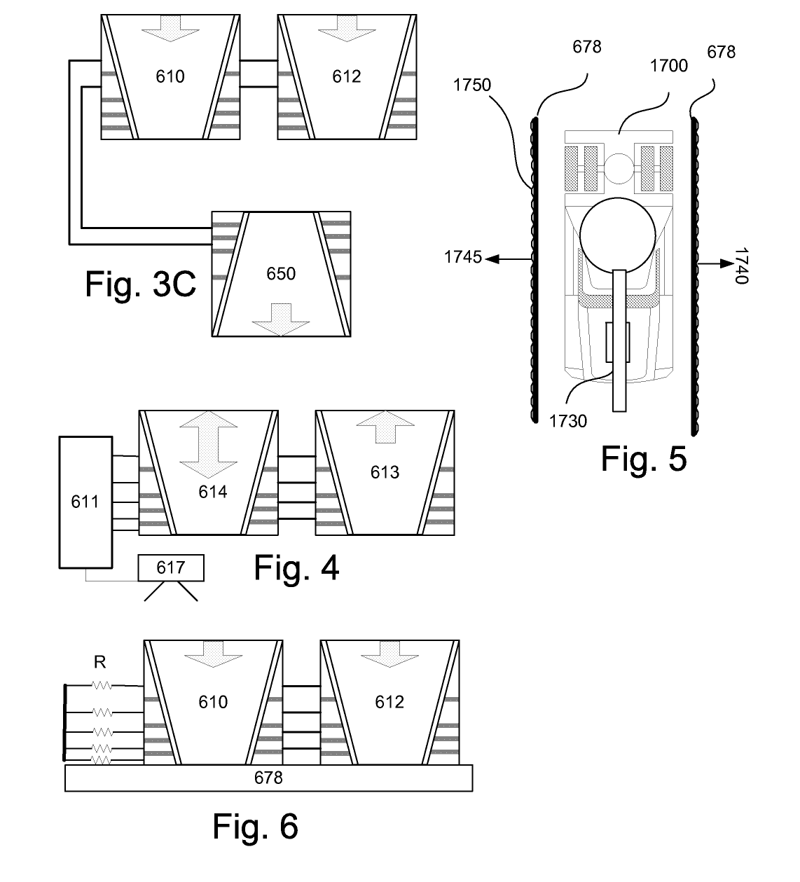

FIG. 3A depicts a simplified embodiment of a single imager cell utilizing CRTRs, and providing radiant energy manipulation. A plurality of such cells would be combined for a complete device, which will be referred to herein as CRTR imager. CRTR imagers may be used in a variety of devices, such as adaptive and/or augmented vision applications, such as night goggles, thermal imagers, visors and helmets, eyewear such as eyeglasses, windshields and windscreens, and the like. Commonly such device will also comprise other elements such as frames, lens, collimators, controls, and the like.

The imager, or the sensor portion thereof coupled to a computer, provides a system capable of detecting hyperspectral or multi-spectral images. Such capacity has relevance in mineralogy, chemical imaging, agriculture, astronomy, surveillance and tracking applications, targeting applications, threat detection applications, and in characterizing a known environment over time, such as intrusion for detection.

Radiant energy 620 is admitted into a CRTR 610 operating as a splitter. The splitter splits energy admitted via the aperture into spatially separated spectral components which are directed to a respective plurality of transducers 622, 623, and 624, which operate at least in LE mode. The transducers detect incoming energy at specific bands and convert the energy to a low frequency signal. Thus CRTR 610 with transducers 622, 623, and 624 form a sensing CRTR based pixel. The low frequency signal is manipulated before being delivered to the display portion. Examples of manipulations may include amplification, digital and/or analog processing, attenuation, coupling of a plurality sensing CRTRs or transducers from one or more pixels to be displayed on a single emitting pixel, varying treatment of certain areas or frequencies, augmenting information in accordance with external data, data transfer and translation, and the like. A simple case is depicted in FIG. 3A, where the signal is linearly manipulated by amplifiers 625, 626, and 627. The amplified signals are coupled to EL transducers 662, 663, and 664 respectively, which in turn convert the amplified low frequency signals, and output light corresponding to the signals. Transducers 662-664 are disposed to impart the light into emitting CRTR structure 650, which operates as a combiner to combine and emit amplified light 670 via its aperture. Notably, any desired type of pixel, including non-CRTR based pixels, may be utilized, but as seen, the CRTR based pixel is highly efficient and its use in this application will be advantageous. The resulting structure will provide the ability to detect radiant energy via the sensing pixel, manipulate the detected signals, and feed the manipulated signals to the emitting pixel, which in turn displays it to the user. The imager may amplify the spectral components received in each of the channels, attenuate or enhance one or more spectral components, translate the frequency of one or more channels, and the like.

In some embodiments each of the transducers 622-624 is optimized for the frequency band it receives, to provide high detection efficiency, reduce noise, and the like.

Active and thermal sources will typically emit randomly polarized energy while reflected images will exhibit some polarization preferences. As described above CRTRs of certain core geometries and transducers are capable of separately detecting differing polarization. Thus the imager pixel may be made sensitive to polarization by utilizing either asymmetrical or multi-faceted symmetrical tapered CRTR cores. Such polarization may be utilized for processing the signal, and may be displayed to the user as direct polarized or non polarized image, or as processed image, enhanced to show certain characteristics. Signals from transducers disposed to receive different polarizations in the sensing pixels may be directed to transducers emitting different colors from the display pixel and may be utilized for low power, low cost polarization sensitive imager.

If desired, control circuitry 651 may be coupled to the CRTR 610, and perform processing of the signal before, after, or instead, of amplification by amplifiers 625-627. Such processing may emphasize a portion of the spectrum, attenuate or enhance certain spectral components, perform analysis such as frequency, intensity, and/or polarization based image interpretation, and change the signals provided to light sources 662-664 in accordance with the results of the analysis. In such embodiments the circuitry may drive those light sources directly, acting as the amplifiers, and optionally replacing them. In other embodiments the control circuitry may simply control the amplifiers. The circuitry may be analog and may combine one or more functions. Such analog circuitry may include by way of non-limiting example, gain control, threshold circuits, squelch circuits, dimming circuits, and the like. Alternatively or in addition, circuitry 651 may be digital such as application specific logic, a Central Processing Unit, a Graphical Processing Unit, a Digital Signal Processor, and the like. Sensed image may be used to dictate the type of manipulation to be performed on the sensed spectral components. Signal processing may algorithmically deduce information and manipulate the displayed picture to obtain desired results, such as removing or attenuating high illumination sources such as sun disk and specific muzzle flashes, reduce specular reflections, enhance and/or highlight radiant energy sources such as IR targets, and the like. Thermal image detection could provide data overlay or object outlining in augmented vision or, under insufficient lighting, the visible light image could be replaced or blended with thermal image display.

Optionally, the circuitry is coupled to a sensor, which may be integrated in the imager, or external thereto. By way of example, orientation sensor 631 may be coupled to the control circuitry 651. If the imager is used by an aircraft pilot or aerial observer for example, the orientation sensor may aid in reducing blue light to portions of the sensed image which correspond to the sky, so as to increase visibility of objects in front of the blue background. Other sensors may be coupled to the control circuitry.

Optionally, the circuitry 651 combines information from several spectral components and intensities. Thus by way of example heat signature information may be analyzed alone or in combination with other spectral components, and the results overlaid and displayed over visible spectrum information. Combinations of polarization information, differing portion of the spectrum, and the like may thus significantly enhance the displayed information and allowing the user or a computer to differentiate between camouflaged objects due to heat, visible, and polarization information. Differentiation between actual objects versus decoys of such objects is also enhanced due to differing responses of the objects at a broad spectrum range. Thus for example a metallic object may be differentiated from a non-metallic object by comparing the expected heat absorption and reflectance, and/or polarization of the two objects. By comparing an image against known signatures of the image, discrepancies may be pointed out.

Further optionally, controlled illumination of targets may also be provided by incorporating one or more EL transducers into the sensing pixel stratum. Optionally, a laser transducer may also be incorporated, in the sensing pixel, to provide laser designation of desired targets and/or locations.

In certain embodiments the control circuitry also allows enhancement of the resulting image from external sources such as a computer for providing augmented reality, radar, communications from users or sensors located elsewhere, stored information regarding the operating environment, textual and/or image communications, and the like. Optionally the control circuit may comprise a switching matrix, allowing programmable routing between transducers in the sensing pixel and transducers in the displaying pixel, and/or routing of power to transducers in either the sensing or the display pixel. The control circuitry can optionally serve as a logarithmic compressor/expander of energy intensity so that the eye perceives a viewable image over wide ranges of ambient light conditions. The control circuitry may be combined with all the imager embodiments to provide any or all of the desired image enhancement.

FIG. 3B presents a simple frequency translation imager. While the structure is similar to that depicted in FIG. 3A, in this embodiment the output of transducer 622 is directed to light source 662′, which is of different spectral range. Therefore, one or more color bands such as IR can be translated to a different band, where LE transducers in sensing CRTR 610 provide a signal for amplification and the amplified signal is fed to EL transducers such that the output of the EL transducers is coupled to CRTR 650. However as the EL transducers of CRTR 650 are of different frequency, the outputted energy 670 contains information obtained from the sensed frequency band. Notably, in the drawing only one of the bands is translated: wherein the output of LE transducer 622 is amplified and coupled to EL transducer 662′, the output of EL transducer 662′ is of different frequency, as may be seen by the offset location of transducer 662′. The output of other transducers may or may not be translated, according to the application at hand. Thus considering the imager depicted in FIG. 3B infrared light may be translated to visible light, by way of example, while blue and green light is merely amplified.

FIG. 3C depicts schematic diagram of a low power imager, where the output of two or more sensing CRTRs 610 and 612, is combined to power the output of one emitting CRTR. Sensing CRTRs 610, 612 absorb incoming energy and detect it. The high efficiency offered by the CRTRs, especially when combined with optional lateral waveguide based transducers, allows low power operation. The output of two or more sensing CRTRs, derived from the incoming energy absorbed by CRTRs 610 and 612, is summed and used to provide output in a corresponding emitting CRTR. It is generally the case that higher frequency light source requires higher voltage as compared to lower frequency. Furthermore, some losses are always present in conversion from one energy form to another. Therefore connecting a single transducer detecting low frequency to a higher frequency EL emitter would require enhancement. Serial connection of more than one sensing transducer provides higher voltage output, which will permit translation to higher frequency.

FIG. 3C therefore depicts one cell of a CRTR Imager, where a plurality of sensing pixels are coupled to a smaller number of emitting pixels.

In certain embodiments an array of imager cells may be embodied in eyewear devices. Optionally, the display portion of the imager may emit light onto a partial reflector placed in front of the wearer eye.

Further optionally, the display may reflect image created by processing circuitry. For example, the display may deemphasize certain ambient colors. By way of example for aircraft pilots it is desirable to attenuate some of the blue colors of the sky to enhance visual detection of objects in the sky. Thus, the sky image may filter a large portion of the incoming blue light, while the land image using either a neutral, or more likely computer enhanced vision, IR vision, and the like. Removal or attenuation of such colors may occur by signal processing, which is optionally assisted by horizon sensors, attitude sensors, accelerometers, and the like.

Depending on the structure, design and mode of operation of the CRTR based imager, certain pixels may emit some wavelengths and absorb or detect other wavelengths, either simultaneously or at separate points in time. By way of example a single sensing pixel may scavenge power from one spectral channel, sense an image pixel in another channel, illuminate a target from another channel as a static light source, and display a time varying intensity in yet another channel. Arrays of pixels may contain elements performing different functions or combinations of functions. Such flexibility is enabled because each CRTR has a plurality of channels and each channel may terminate in a one of a large selection of LE or EL transducer types, such as reflectors, light modulators, CCD devices, CMOS devices, photocells, photovoltaic transducers, and the like. Therefore the imager may be utilized at least partially as its own power source, as a light source, and as a display or light based communication device.

Clearly, any improvement in signal to noise ratio (reduction in the pixel noise figure) will improve performance. In order to reduce dark current and other thermal noise processes and to maximize internal gain, CRTR imagers may be cooled. Sequential and spatial binning may also be employed to effectively reduce noise (by adding coherent signal). Since the gain may be adjustable, such systems operate from a relatively low level of light up to ambient daylight and even intense light situations, making them very attractive for applications in which sudden variation in light conditions may occur.

Amplification of alternate transducers, such as PV, reverse-biased LED, photodiode, nano-bolometers, rectennas, and the like is also possible. In all such cases, further improvement to the noise figure is always desirable, as is a reduction in size, weight, and power (SWAP) and cost.

In yet another approach, the infra-red light emitted by black body radiation from all objects is detected. Variations in local temperature are detected as variations in intensity. The detected information is then color and intensity encoded as a visible image using various mapping algorithms.

In order to reduce dark current and other thermal noise processes and to maximize internal gain, imager systems are oftentimes cooled. In some systems, the light amplification gain may be adjustable, manually or automatically.

So in this aspect of the invention, there is therefore provided an imager comprising a plurality of CRTR based sensing pixels forming a sensor portion, the sensor being coupled to a display optionally comprising of a plurality of CRTR based emitting pixels. In some embodiments at least some of the sensing pixels are configured to detect a plurality of polarizations. In some embodiments at least some of the emitting pixels are configured to emit energy in multiple polarizations. In certain embodiments at least one spectral frequency detected by the sensor or a portion thereof is emitted by the display or a portion thereof as a different spectral component. Optionally the sensing pixels are arranged on one side of a substrate and the emitting pixels are arranged on an opposite side thereof.

Optionally emitting pixels are configured to also emit energy with programmable spectral content, such as computer generated images and symbols. Further optionally at least some of the sensing pixels operate in hybrid mode and are configurable to emit illuminating energy. The illuminating energy may be in the visual range, in the IR range, or in any other desired frequency range. The illuminating energy may be utilized to illuminate and/or mark a target, for line-of-sight communications, and the like. In some embodiments, the device further comprises a battery or other energy storage, which is being charged by energy harvested from the receiving or hybrid CRTRs, such as charging during day time by way of example.

In some embodiments at least some of the pixels are capable of at least partially providing their own power by harvesting a portion of the admitted and/or injected energy. In certain embodiments the output of at least two sensing pixels in at least one spectral band is connected to provide power to only one emitting pixel, or alternatively to a plurality of emitting pixels having a smaller number of emitting pixels than the plurality of sensing pixels which provide power thereto.

While most embodiments will require a lens placed in front of the CRTR based sensor, collimators may be placed in front of each sensing CRTR, instead, or in combination, with lenses, prisms, and the like.

Other aspects of the invention provides for reducing visual, heat, and/or radar signature of certain military related objects and personnel. Thus, there is further provided a photonic covering comprising an array of pixels. The pixels may be able to perform at least one of a) controllably reflecting incident radiant energy, b) Controllably harvesting incident radiant energy, c) controllably emitting radiant energy at selected wavelengths, and d) any combination thereof. The covering may control such activities in either a static or programmatic fashion. Such covering could serve to camouflage an object both by modifying the thermal emission of the object and by modifying the reflectance of the object to external light sources. The covering may be embodied in a covering permanently applied to an object such as a vehicle, or as an actual covering such as a camouflage panels or camouflage nets, or to clothing of soldiers, and the like.

Thus, in one embodiment of the invention, a plurality of CRTR based emitting and/or reflecting pixels are embedded in a covering of an object such as a coating of a vehicle, clothing items, camouflage nets, aircraft, ship and the like. A camouflage pattern is displayed by the pixels to assist in reducing the shape or signature of the object. FIG. 4 depicts a simplified block diagram of a portion of such array. Pixels 613 and 614 represent but two of the plurality of pixels attached to or embedded in the object or its covering. The pattern emitted by the plurality of the pixels is preferably controlled by controller 611. Controller 611 may be embodied as a simple switching device that allows selection between several predetermined patterns, however it may also be a programmable device, allowing a larger variety of patterns. Optionally the controller 611 may utilize an optical sensing device 617 such as a camera or a CRTR based sensor to select the pattern emitted from the emitting/reflecting CRTRs 613, 614. The CRTRs 613, 614 may actively emit radiant energy from EL type transducers, reflect certain portions of the ambient radiant energy, or any combination thereof. As the resolution required is generally coarse a plurality of CRTRs may be connected together. Some embodiments may incorporate CRTRs combined with energy harvesting transducers.

An array of such CRTR based pixels is able to modulate its optical and other radiant energy characteristics such as emitted and/or reflected spectrum over a broad band of frequencies and/or polarizations, extending the capability for camouflage into the UV and IR spectrums and even extending potentially to mm waves. By spatially and temporally modulating such reflectance, emissions, and similar characteristics, the outlines of an object would be much harder to detect.

A portion of FIG. 4 depicts yet another optional feature of the present embodiment, where CRTRs 614 is shown as being operated in a hybrid mode. The hybrid mode is provided to demonstrate both the option of powering the camouflage arrangement from incoming radiant energy, and the reflective pixel. While self powering camouflage arrangement is advantageous for many embodiments, the hybrid CRTRs is especially useful in combination with another aspect of the invention. Soldier clothing utilizing any combination of reflecting/emitting pixels are a part of the invention. However when a plurality of sensing or hybrid CRTRs based pixels are embedded in the clothing, and at least some of the sensing or hybrid pixels utilize transducers directed at energy harvesting, the clothing are not only self powering but may be used to operate other electronic devices. Such energy harvesting transducers are generally PV and/or rectenna based.

Therefore, another aspect of the invention provides a camouflaging device and/or arrangement comprising a coating coupled to an object to be camouflaged, the device comprising a plurality CRTR based emitting and/or reflecting pixels, the pixels having EL and/or RL transducers, and a controller coupled to the plurality of pixels for controlling the radiant energy emitted therefrom. Optionally at least one of the emitting pixels is operated in hybrid, and being coupled to an LE transducer for harvesting energy incident on the camouflage device. Optionally the device further comprises an optical sensing device coupled to the controller. Such optical sensing device may be a CRTR based device or any other image sensor, and the output thereof is used by the control circuitry to facilitate selecting the most effective camouflage pattern to be emitted by the emitting/reflecting pixels.

As described about the imager above, at least some of the pixels may be selectively used for illumination, communications, and the like.

One can place CRTRs on helmets and other hard gear Such gear may have a combination of emissive (specific IR narrow band in a soldier selected direction), reflective (of different colors either at soldier selection, or responsive to some sensed environment) and energy harvesting.

Certain regions directed to communications may be located at the helmet perimeter. the zones contain a plurality of emissive CRTR's for a narrow spectrum light band, line of sight communications. As described above a plurality of CRTRs may be used in combination with a phase sequencer to form a narrow beam in a desired direction. Selecting a direction may be done by tracking a soldier's progress from previous communications. Once a soldier location is determined, a beam is sent at specific frequency and possibly specific polarization, while parameters are sent as noise. In such system encryption occurs with minimum, if any, processing.

The helmets may also serve to locate a soldier in the field if IR light of specific color and/or orientation is emitted upon a remote request, in a desired direction. Adding a location and orientation sensor to such helmet together with GPS information would allow limiting the communications to a very narrow line of site between two end stations. The helmet would of-course serve other needs such as energy harvesting, camouflage, and the like. As the helmet serves primarily as a carrier to the camouflaging arrangement in combination with other features and aspects of the present invention, a specific drawing is not required.

FIG. 5 depicts a simple use of a camouflaging covering 678 implemented in standalone panels deployed to camouflage a vehicle 1730. The patterns 1740 and 1745 emit and/or reflect radiant energy which obfuscate the shape of the vehicle. At least the outer side or the covering, depicted in the drawings by the arrows, will have a plurality of CRTR based emitting and/or reflecting pixels such as 610, 612. The pixels may also be added to the vehicle skin 1700.

FIG. 6 depicts yet another embodiment utilizing a plurality of CRTRs to reduce radar signature of objects such as vehicles, aircrafts, marine vessels, and the like. A coating 678 is applied to the object, the coating comprises a plurality of sensing pixels 610, 612. LE transducers in the pixels are tuned to desired range of frequencies, and the CRTRs themselves are dimensioned to admit incident energy of at least the spectrum of interest, which in this case will be the radar range. Radar energy that is directed at the object is admitted into the CRTRs and absorbed by the transducers. The absorbed energy may then be used by a load such as resistors R, stored in energy storage, or merely dissipated as heat.

Therefore, in another aspect of the invention there is provided a coating for a vehicle comprising a plurality of millimeter wave and/or microwave tuned CRTR, coupled to radiant energy transducers in the same spectral range, wherein the transducers convert the incoming energy and thus reduce re-radiation of the energy. Converted energy may be utilized by the vehicle and further may be analyzed to determine the type and optionally the direction of the threat. Such harvesting turns most of an aircraft or other vehicle to a ‘wave sink’ by covering it with rectenna based CRTR's which will reduce significantly the radar signature by absorbing the radar wave energy. Reversing the array so that the CRTRs are all facing inward would provide reduced leakage of emitted signal over a broad bandwidth

Therefore there is provided a device for reducing radar signature of an object, the device comprising a plurality of superposed lateral waveguides coupled to the object, and having at least one LE transducer disposed therewithin, the transducer being coupled to a load. A plurality of CRTRs embedded within the lateral waveguides are dimensioned to absorb radar energy and direct at least a portion thereof to the transducers, and the transducers being capable of convert the radar frequency energy into electricity.

An aspect of the present invention provides improved performance for several of the embodiments described herein, such as display, camouflage and radar absorption by way of example. The optional arrangement of CRTRs and/or CRTR based pixels as shown in FIGS. 6 and 6A is constructed from a plurality of CRTR's arranged in clusters. Each cluster is constructed to direct one or more CRTR's at a different angle. Thus for example if a truncated octagonal pyramid 1750 is provided and each face, including the truncated surface 1780, had one or more CRTR's 1760 embedded therein, an observer will see the desired patterns from a far wider range of viewing angels, regardless of the position from which he is looking.

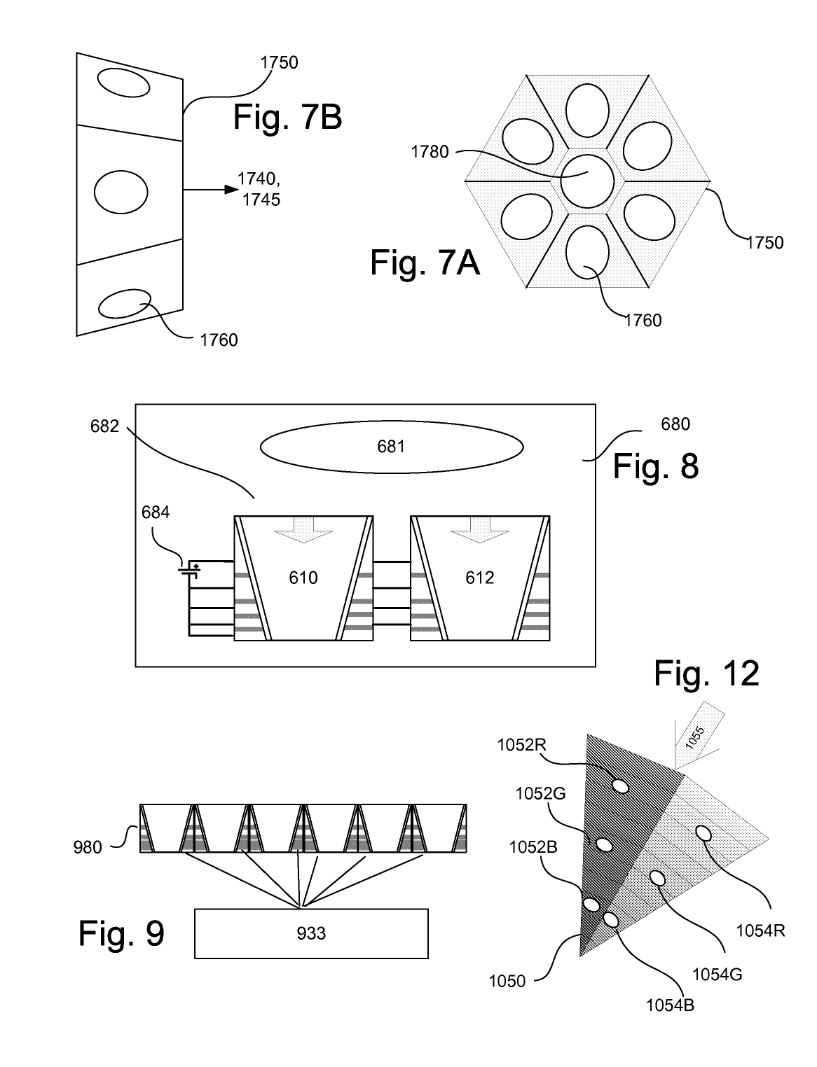

The object to be camouflaged may be hidden between screens or may have the structure on its own surface, in whole or in part. The surface is textured such that it provides a large plurality of surfaces directed at various orientations. The example shown in FIG. 6 shows such surface having protrusions or depressions such as truncated octagonal pyramid 1750. FIG. 7A is a front view of such protrusion/depression, and FIG. 7B is a side view. Any desired shape may be used for the depression/protrusion, but it is believed that geometrical shapes will be easiest to manufacture. The depression/protrusions shall be related to as ‘dimples’.

Each of the faces of the pyramid 1750 hosts at least one CRTR, and optionally more. In some embodiments one side acts as sensing CRTR's and the other as emitting CRTR's. Alternatively both sides may act as bidirectional CRTR's. In some embodiments transducers may be shared by all CRTRs on one face of the dimple, or even by all CRTRs of a dimple. One side of an object may be used for sensing and energy harvesting, such as in cloaking an aircraft from the ground, where the bottom of the aircraft is covered by emitting CRTR's and the top is covered by sensing/energy harvesting CRTR's. Judicial material selection will provide dynamic reconfiguration of emitting and sensing elements which will allow changing of the object camouflage configuration in the filed. Hemispherical dimples (not shown) may also be provided.

While the above does not provide a complete camouflage, it certainly assists in hiding the general shape. While used against substantially homogenous background, such as forest, desert, sky, etc, this invention may provide sufficient hiding to make an object disappear and at least hard to discern even when moving. For a device that normally uses camouflage nets, using this device offers hiding that easily matches the environment by a simple activation of a switch. Computer algorithms may be developed to provide improved hiding.

If desired, computer generated images or patterns may be drawn into the one or more of the surfaces, to provide the equivalent of camouflage netting or any other desired image. Doing so may be achieved by connecting sufficiently large clusters of CRTR's to a computer.

A piezoelectric device may be placed in the cluster for changing the shape of a dimple by controllably extending and contracting of the whole dimple, or one or more edges.

In radar signature reduction applications the dimples will increase the absorption area that is at right angles to the interrogating radar beam. In display applications the use of dimples results in larger usable viewing angle. Therefore, as shown by way of example, there is provided an improvement to several aspects of the invention by arranging a plurality of CRTRs on different faces of a geometrical shape such that at least a portion of the plurality of CRTRs are arranged to be non-parallel to each others.

FIG. 8 depicts an embodiment directed towards reducing the heat signature of a vehicle or person. Heat is generated in a vehicle by a number of potential heat sources like the engine, compression chamber, and the like. Human metabolism generates heat. Heat makes humans and machines vulnerable to detection. The vehicle or a portion thereof defines an envelop that at least partially contains at least one of the heat sources, the envelope is symbolized by box 680. While the envelope may be defined by the vehicle skin, it may also be defined by internal components such as baffles, compartments, and the like. Leakage of heat from heat generating components 681 inside the envelope is reduced by an IR LE absorber 682. The absorber is capable of absorbing IR energy and have at least one active face. The active face is directed TOWARDS the heat generating component, and thus heat energy is absorbed and is either stored in batteries, capacitors, and the like 684, or otherwise dissipated. In effect by placing the IR absorber between the heat generating device and the vehicle envelope, energy is absorbed and diverted, thus lowering the amount of energy reaching the envelop, and reduce heat leakage outside the vehicle envelop. In FIG. 4B the IR LE absorber is depicted by CRTRs 610 and 612, but the skilled in the art will recognize that any other IR absorber may be utilized. This embodiment of the invention is advantageous over thermal insulation as the heat energy is conducted away from the heat sources and converted to electrical energy, the thermal leakage is lower, in addition to the additional efficiency derived from the recovered energy. The energy may be stored or dissipated in place hidden from detection.

Reducing the heat signature of a person may be done in a similar way, if an IR absorber is placed in clothing worn by the person, and the absorber is directed to best absorb the body heat. This is done by directing the active side towards the body.

FIG. 9 depicts simplified example of yet another aspect of the invention which is applicable both as an independent device, and as an additional feature to many of the other aspect of the invention. By feeding a plurality of closely spaced emitting pixels 980 a pattern of signals having different phase relationship therebetween, a phased array antenna is created, allowing forming and steering of a beam of radiant energy. A phase sequencer 933 is used to feed such signals. The phase sequencer is optionally capable of changing the intensity of the signal outputted to the pixels. Phased array technology is well known and shall not be recited herein, but the use of this technology in CRTR based pixels offer significant advantages. By feeding controlled phase, and optionally also controlled amplitude, energy to a CRTR based pixel array a very narrow beam steerable beam may be formed. Laser transducers, IR transducers, and longer wave transducers may be used. Edge-emission lasers disposed within lateral waveguides are especially useful due to the high power capabilities of such lasers. The beam may be used for target illumination, line of site communications, area illumination, and the like. This embodiment may be utilized on any of the aspects of the invention described herein.

A sensing millimeter/microwave CRTR operating with a plurality of transducers in varying depths forms a channelized filter integrated into a horn antenna wherein the channelized ports are lateral to the horn and the tip exit port is a high pass filtered output for a broad band input. Therefore the CRTR acts not merely as a side fed horn antenna, but taking the signal from each transducer allows handling of sub-bands separately, reducing noise and increasing antenna merit. Therefore, there is provided a front end for electromagnetic radiant energy receiver, comprising at least one, and preferably a plurality of CRTR's, each having a plurality of transducers arranged to receive differing frequency bands, wherein each of the transducers of at least one of the CRTRs receives one of the sub-bands. Preferable, the signals from a plurality of respective transducers from a plurality of CRTRs are combined to form enhanced signals at the respective sub-band.

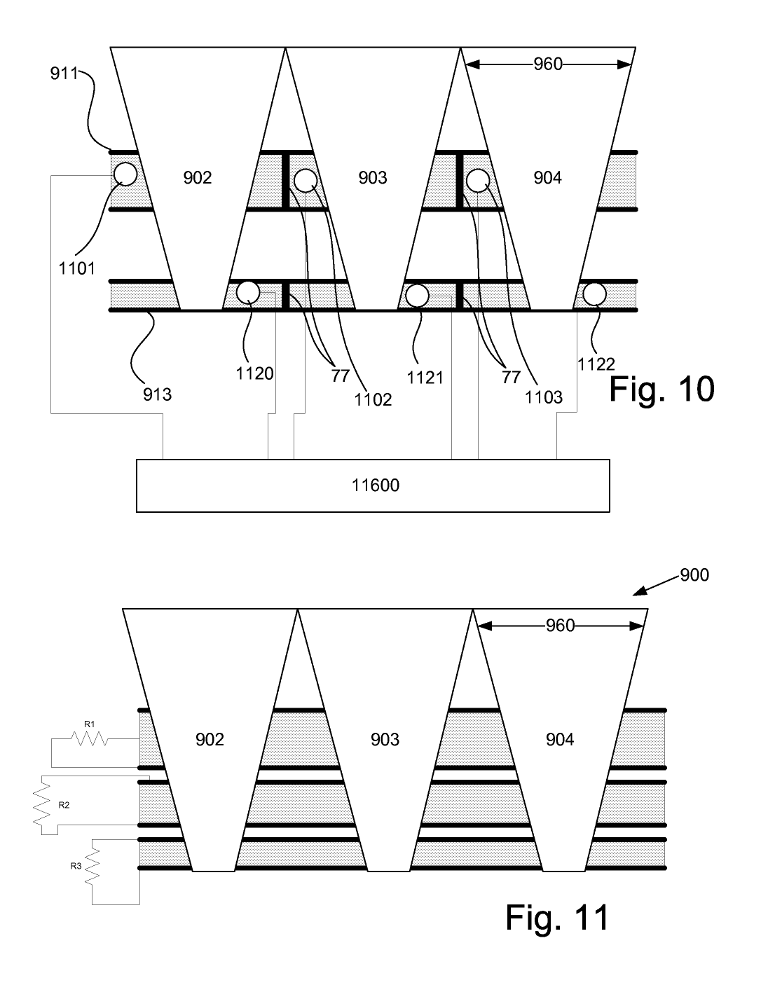

FIG. 10 is a more detailed view of a portion of a larger phase array antenna. Firstly, separators 77 isolate each CRTR from other CRTRs so that each CRTR 902, 903, 904, operates as an independent radiating element. A transmitting antenna is described, but a receiving antenna will operate similarly if LE transducers are utilized. Radiating source transducers 1101, 1102, and 1103 couple energy of a first frequency via the cladding into the respective CRTR core. Phase controller 11600 controls the relative phase, and optionally also the relative intensity of signals going to the radiating transducers, and thus the phase of the signals emitted from each individual CRTR. As known, the direction, and optionally the shape, of the beam emitted from the CRTR array, is controlled by the phase difference between individual elements.

Optionally additional radiating source transducers such as 1120, 1121, and 1122 couple energy at a second frequency via the cladding into the respective CRTR core. As the CRTR is capable of mixing signals of very broad band, the antenna array can be used to send more than one beam and steer the beams individually. Thus each CRTR and its associated transducers form a versatile transmitting element, by emitting radiant energy from the apertures 960 in a manner that will cause wave interference, the array can steer a beam emitted form that antenna by varying patterns of phase and/or amplitude relationship between separate transducers in the array, by the phase controller. Optionally the transducers are disposed within lateral waveguides 911, 913.

As a CRTR is a linear, bidirectional device, the antenna can be used as a receiving antenna by utilizing LE transducers as receiving elements. When configured for receiving operation the phased array antenna can provide information regarding the direction of incoming signals. The receiving transducers may be placed so as to receive radiant energy entering the CRTRs, forming a receiving antenna from each transducer/CRTR combination, where the receiving direction is detected by the relative phase and/or intensity of signals received from a plurality of CRTRs. The phase controller/sequencer 11600 is then replaced by, or is in combination with, a signal processing unit that analyzes the differences between the signals received from different receiving transducers. While most phased array antennas operate best at a specific frequency and its harmonic, the broad-band nature of the CRTR offers a phased array receiving antenna of very broad spectrum. Such antenna is very useful for signal intelligence gathering.

The transducers may be of any desired type or frequency befitting the application at hand, including inter alia laser, EHF, microwave, visible light, UV light, and the like. Notably, radiant sources may also a plurality of lasers, which will allow directing a laser beam to a desired direction, at high intensity due to constructive interference.

FIG. 11 is more detailed depiction of the embodiment of FIG. 6, representing a portion of a coating for a vehicle comprising a plurality of millimeter wave and/or microwave tuned CRTR, coupled to radiant energy absorbers. Such absorbers may be as simple as resistive loads such as R1, R2, and R3, convertes that convert the incoming energy into another form of energy, and the like. The absorbers and converters convert the incoming energy and thus reduce re-radiation of the energy. As parts of the radiant energy is not reflected, the radar signature or IR signature will be reduced. Converted energy may be utilized by the vehicle and further may be analyzed to determine the type and optionally the direction of the threat. Such harvesting turns the covered portions of an aircraft or other vehicle to a ‘wave sink’ by covering it with CRTR's which will reduce significantly the radar signature by absorbing the radar wave energy. Rectennas are preferred for harvesting energy at the radar and EHF bands.

Reversing the array 900 so that the CRTRs apertures are facing into the inside of the vehicle would provide reduced leakage of emitted signal over a broad bandwidth. A combination of inward and outward facing CRTRs would reduce the electronic signature or vehicles equipped with this embodiment of the invention. As the skin of the vehicle is now a phased array antenna, data about electromagnetic radiation in the vicinity of the vehicle may be collected and used for intelligence, alerting, and the like.

FIG. 12 represents a perspective view of one CRTR having a square core 1050, and transducers 1052 and 1057 which will detect energy at respective 90° polarization to each other. FIG. 8c shows the optional feature of a combination of frequency and polarization detection or mixing. While the CRTR 1050 operates in splitter mode, radiant energy 1055 is admitted to the CRTR core 1050 via the aperture and travels along the depth direction towards the tip. The energy is divided between the different transducers groups 1052 (R, G, and B), 1054 (R, G, and B), such that each transducer receives a spectral component separated by polarization as well as by frequency. Thus by way of example, the pair 1052r and 1054r would each receive a spectral component of a red frequency, but of differing polarization, and similarly transducers 1052g and 1054g would receive a spectral component of a green frequency but with differing polarization, and transducers 1052b and 1054b will have the same with blue frequency. Clearly, if desired a single frequency radiation may be detected by including only a pair of transducers, or polarization only may be detected for a wider range of frequencies by directing the multi-frequency spectral components emitted from varying depths into a single transducer for each polarization.

As described above, CRTRs are commonly disposed within stratum which may comprise a slab or more commonly a plurality of superimposed waveguides known as lateral waveguides. Layers and portions of the stratum may be formed as a single undivided layer, or may be divided into sections. Sections may be separated electrically and/or optically, and the barriers between the different sections will generally be referred to hereinunder as “baffles”. A common division is to provide baffles to separate the region around a single CRTR and thus create a single CRTR pixel; however, divisions containing more than one CRTR may exist as desired. A pixel may be an emitting pixel, a sensing/harvesting pixel, or a combination thereof. The stratum may also comprise circuitry such as conductors, vias, and the like as required for connecting individual pixels. The stratum may also contain active and passive electronic components, such as amplifiers, controllers, switches, and the like. In certain embodiments the stratum may comprise inactive layers.

The stratum material is a matter of technical choice; however, good reproducibility of its index of refraction, capability of being deposited at sub-micron to micron-scale thicknesses with good uniformity, precise thickness control, and low stress are highly desired, as are good adhesion to the substrate and compatible thermal properties. Spin on glasses, such as polymethylsiloxanes, polymers such as polymethylmethacrylate (PMMA) and parylene, oxides and nitrides, such as silicon-aluminum oxy-nitride (SiₐAl_{b}O_{c}N_{d}, including sialon®) and the like are all potential stratum material. The skilled in the art would recognize many other well-known materials providing the desired properties.

The cladding of CRTRs and/or the stacked waveguides may comprise a plurality of materials and may be deposited in several stages. Aluminum, silver, copper, and gold are among the many candidate metals that are highly reflective, electrically efficient and chemically stable, although numerous other examples are readily considered. At optical frequencies the skin depth is on the order of 1-5 nm and thicknesses of continuous metallic claddings may be on or below this order. Use of metallic claddings imposes few constraints on the core material other than thermal compatibility and transparency over the spectral range of interest. Some metals form discontinuous films on some substrates even at thicknesses in excess of the skin depth. Such discontinuous (porous or perforated) metal films are also known to be semi-transparent near normal incidence at thicknesses approaching tens of nm, and such discontinuous metal cladding is also considered. Cladding may also be a low refractive index dielectric material, polymers, and the like. Silicon dioxide, Parylene-N, are but two possible candidates for cladding materials.

Efficient total internal reflection of the energy in the CRTR core suggests that the core have higher refractive index than the cladding and that the cladding have a minimum thickness sufficient to totally internally reflect the wave until approximately the critical angle, at which a cladding penetration state is abruptly reached.

At wavelengths from about 3.5 μm to about 20 μm rectennas and other plasmonic direct detection schemes are promising. In this band the frequencies are theoretically compatible with atomic layer deposition (ALD) MI2M tunnel diodes and there are plausible fabrication methods for 1.5 to 10 μm long nanowires electrically attached to the lower metallic surface of a lateral waveguide and atomic-layer spaced from the subsequent layer. Such nanowires would form a λ/2 “inside-out” dipole in which the feed points are low impedance nodes of the antenna resonance, one attached to a ground plane and one connected by a tunnel diode to a signal trace within a collector. Small arrays of such rectennas surrounding the CRTR at the appropriate depth in the substrate offer relatively wide dynamic range transducers at frequencies below the RC time constant cutoff of the tunnel diodes. Multiple layers of such small arrays at different center frequencies could be built for multi-spectral IR imaging. Rectennas are also especially fit for harvesting energy in the IR range and will provide excellent results when deployed to recover waste hit such as from inside chimneys, around boilers, exhaust pipes, etc.

HgCdTe (Mercury Cadmium Telluride) is able to detect a wide range of infrared radiation and thus presents an option for certain classes of sensors for at least some layers of a CRTR based lateral waveguides based sensing pixel. The cooling requirements for HgCdTe is expensive in the LWIR range and here rectennas may offer the better alternative. MWIR HgCdTe cameras can be operated at temperatures accessible to thermoelectric coolers with a small performance penalty. However, in many applications this is also undesirable and improved MIM tunnel diodes are therefore considered.

Photodiodes can be used as sensing elements and implemented in the lateral waveguide layers using amorphous or polycrystalline silicon, germanium, indium gallium arsenide, and the like. Combined with the filtering inherent to the CRTR, these layers of transducers are able to detect from the lowest wavelength SWIR all the way to UV. The sensing elements may be biased as desired, including utilizing black current or avalanche mode, according to the application requirements. In some cases, transistors can also be implemented in these layers. Thin film transistor active pixel sensor (TFT APS) with pixels ranging from 127 μm to tens of μm. More preferably, the sensing elements will be located in the thin film layers between pixels and the amplification and switching transistors will be of much smaller dimensions in a suitable high-quality layer above or below the pixel array.

Circuit elements such as power supply, biasing, amplification, and the like deemed non-essential for understanding the principles of operation of the various aspects of the invention have been omitted from the drawings but will be clear to the skilled in the art.

Many more options for the transducers abound, such as Si bolometers, quantum dots, and the like. Dye sensitized semiconductors and organic PV materials are also optional. It is important to note that transducers/transducers for such sensors may be deployed with or without the lateral waveguides.

It will be appreciated that the invention is not limited to what has been described hereinabove merely by way of example. While there have been described what are at present considered to be the preferred embodiments of this invention, it will be obvious to those skilled in the art that various other embodiments, changes, and modifications may be made therein without departing from the spirit or scope of this invention and that it is, therefore, aimed to cover all such changes and modifications as fall within the true spirit and scope of the invention, for which letters patent is applied.

1. A pixel comprising:
a tapered waveguide core having a first end and a second end, the first end defining an aperture, the core having a depth direction extending between the first end and the second end, wherein the depth magnitude increases with distance from the first end toward the second end;
the core having a monotonically decreasing width dimension in at least one direction transverse to the depth direction;
a plurality of transducers disposed about the cladding;
wherein at least two of the transducers are selected from a LE transducer which converts spectral components of radiant energy admitted into the aperture into electrical energy, the pixel forming a sensing pixel; an EL transducer which converts electrical energy into radiant energy to be injected into the tapered core and at least partially emitted via the aperture, the pixel forming an emitting pixel; a RL transducer which receive a spectral component admitted via the aperture and controllably reflect the spectral component back into the tapered core for being emitted via the aperture, the pixel forming a reflecting pixel, and any combination thereof.

2. An imager comprising: a plurality of pixel elements, at least one pixel element comprising:
at least one sensing pixel and one emitting pixel, as claimed in claim 1 the sensing pixel comprising a plurality of transducers;
wherein the sensing pixel is configured to operationally separate radiant energy admitted via its aperture into a plurality of spectral components and direct the spectral components to corresponding transducers, for converting the spectral components into respective electrical signals;
the plurality of electrical signals is being manipulated and coupled to at least one transducer in the emitting pixel for converting the manipulated signals to radiant energy;
wherein the emitting pixels are configured to receive energy from the at least one of the transducers in the sensing pixel, and emit visible light corresponding to the sensed plurality of spectral components or a portion thereof; and,
wherein the plurality of sensing pixels form a sensor portion of the imager, and the plurality of emitting pixels form a display portion of the imager.

3. An imager as claimed in claim 2, wherein at least one of the plurality of spectral components are being manipulated by at least one of: amplification, attenuation, combination of outputs from a plurality of sensing pixels, combination of outputs from a plurality of transducers in the sensing pixel, digital signal processing, analog signal processing, and any combination thereof.

4. An imager as claimed in claim 2, wherein a first of the plurality of sensed spectral components differs from a second of the plurality of spectral components by at least different polarization.

5. An imager as claimed in claim 2, wherein at least one transducer of the sensing pixel or the emitting pixel is disposed in a lateral waveguide.

6. An imager as claimed in claim 2, wherein at least one of the sensed spectral components is translated to another spectral component prior to being outputted by the emitting pixel.

7. A camouflaging device comprising a covering coupled to an object to be camouflaged, the device comprising:
a plurality emitting or reflecting pixels as claimed in claim 1; and,
a controller coupled to the plurality of pixels for controlling the color of light respectively emitted or reflected therefrom.

8. A camouflaging device as claimed in claim 7 wherein at least one of the emitting pixels is operated in hybrid mode, and having at least one LE transducer for harvesting energy incident on the camouflage device.

9. A camouflage device as claimed in claim 7, wherein at least one of the plurality of pixels is operated in hybrid mode and having at least two transducers of differing types, the types selected from LE, EL or RL transducer, or wherein the plurality of pixel comprises a combination of emitting pixels and reflecting pixels.

10. A camouflaging device as claimed in claim 7, further comprising an optical sensing device coupled to the controller.

11. The camouflage device as claimed in claim 10, wherein the optical sensing device comprises a plurality of sensing pixels.

12. (canceled)

13. (canceled)

14. A method for reducing heat signature of a vehicle having a body forming at least a partial envelope, and having at least one heat producing component at least partially disposed within the envelope, the method comprising the step of disposing a radiant energy to electrical energy converter between at least a portion of the heat producing component and the envelope, the converter having an active face directed toward the heat producing component.

15. A method as claimed in claim 14, wherein the converter comprises:
at least one planar LE transducer disposed within a lateral waveguide; and,
a plurality of tapered core waveguides disposed within the lateral waveguide, wherein the tapered cores having a wide end, and wherein the wide end of the plurality of tapered cores is directed toward the heat producing component, and the tapered cores are dimensioned to admit radiant energy from the heat producing component and direct at least a portion of the admitted energy to the LE transducer.

16-17. (canceled)
